(19) United States
(12) Patent Application Publication
(10) Pub. No.: US 2025/0107068 A1
(43) Pub. Date: Mar. 27, 2025

(54) DUAL WORK FUNCTION WORD LINE FOR 4F2

(71) Applicant: Applied Materials, Inc., Santa Clara, CA (US)

(72) Inventors: Tong LIU, Folsom, CA (US); Sony VARGHESE, Manchester, MA (US); Zhijun CHEN, San Jose, CA (US); Fredrick FISHBURN, Aptos, CA (US); Balasubramanian PRANATHARTHIHARAN, San Jose, CA (US)

(73) Assignee: Applied Materials, Inc., Santa Clara, CA (US)

(21) Appl. No.: 18/886,692

(22) Filed: Sep. 16, 2024

Related U.S. Application Data
(60) Provisional application No. 63/584,426, filed on Sep. 21, 2023.

(51) Int. Cl. H10B 12/00; H01L 21/762

(52) U.S. Cl. CPC H10B 12/315; H01L 21/76224; H10B 12/053; H10B 12/482; H10B 12/488

(57) ABSTRACT

The present technology includes vertical cell array transistor (VCAT) with improved gate induced leakage current. The arrays one or more bit lines arranged in a first horizontal direction and one or more word lines arranged in a second horizontal direction. The arrays include one or more channels extending in a vertical direction generally orthogonal to the first direction and the second horizontal direction, such that the bit lines intersect with a source/drain region of the plurality of channels, and the word lines intersect with gate regions of the plurality of channels. Arrays include where at least one word includes a first section adjacent to the source/drain region and a second section adjacent to the gate region, where the second section contains a high work function material and the first section contains a low work function material.

### CROSS-REFERENCES TO RELATED APPLICATIONS

This application claims the benefit of priority to U.S. Patent Application No. 63/584,426 filed Sep. 21, 2023, the contents of which are hereby incorporated by reference in their entirety for all purposes.

### TECHNICAL FIELD

This disclosure generally describes designs for a 4F² two-dimensional dynamic random access memory array. More specifically, this disclosure describes a 4F² memory array with decreased leakage current.

### BACKGROUND

With advances in computing technology, computing devices are smaller and have increased processing power. Accordingly, increased storage and memory is needed to meet the devices' programming and computing needs. The shrinking size of the devices with increased storage capacity is achieved by increasing the number of storage units having smaller geometries.

Dynamic random-access memory (DRAM) architectures continue to scale down over time. For example, a one transistor, one capacitor (1T-1C) DRAM cell architecture has successfully scaled down from an 8F² size to a 6F² size (where F is the minimum feature size). Further design scheme changes from 6F² to 4F² may help further improve area density. In the 4F² DRAM scheme, a storage node (capacitor) and bit line are located at the top and bottom of a vertical cell transistor, leaving the channel completely isolated from the body. Due to this arrangement, the floating body effect, which is not an issue for current 8F² or 6F² DRAM cell architecture due to the body connection of the channels, becomes a major technical challenge for 4F² DRAM. Therefore, improvements in the art are needed.

### BRIEF SUMMARY

The present technology is generally directed to vertical cell array transistors (VCAT) and methods of forming such VCATs. VCATs may include one or more bit lines arranged in a first horizontal direction, one or more word lines arranged in a second horizontal direction, and one or more channels extending in a vertical direction that is generally orthogonal to the first horizontal direction and the second horizontal direction such that the one or more bit lines intersect with a source/drain region of the one or more channels and the one or more word lines intersect with a gate region of the one or more channels. VCATs include where at least one word line of the one or more word lines includes a first section adjacent to the source/drain region and a second section adjacent to the gate region. The second section includes a high work function material and the first section includes a low work function material.

In embodiments, the low work function material has a lower work function than the higher work function material. Additionally or alternatively, in embodiments, the at least one word line includes a third section adjacent to a second source/drain region. In further embodiments, the third section includes a second low work function material. Moreover, in embodiments, the second low work function material is the same material as the low work function material or is a different material. In embodiments, the high work function material exhibits a work function that is at least about 2% greater than a work function of the low work function material. In yet more embodiments, the low work function material has a work function of less than or about 4.2 eV. Furthermore, in embodiments, the high work function material has a work function of greater than 4.2 eV. In embodiments, the source/drain region includes a Schottky contact or an Ohmic contact. Moreover, in embodiments, the VCAT also includes a gate extending in the second horizontal direction and formed around at least a portion of the one or more channels.

The present technology is also generally directed to VCATs having a plurality of bit lines arranged in a first horizontal direction, a plurality of work lines extending in a second horizontal direction, and a plurality of channels extending in a vertical direction that is generally orthogonal to a first horizontal direction and a second horizontal direction such that the plurality of bit lines intersect with a source/drain region of the one or more channels and the plurality of work lines intersect with a gate region of the one or more channels. VCATs include where at least one word line of the plurality of word lines include a first section adjacent to the source/drain region, a second section adjacent to a gate region, and a third section adjacent to a second source/drain region. VCATs include where the second section contains a high work function material and the first and third sections include a low work function material.

In embodiments, the first section extends from a bottom of the word line to a height above a plane generally coplanar with an upper surface of an adjacent source/drain region. In more embodiments, the second section extends from an upper surface of the first section to a height below a plane generally coplanar with a lower surface of the second source/drain region. Moreover, in embodiments, the third section extends from an upper surface of the second section to a height below an upper surface of the adjacent channel. In yet further embodiments, the second section includes molybdenum and the first section and third section include polysilicon.

The present technology is also generally directed to methods of forming VCATs. Methods include etching a substrate to form one or more shallow trench isolations and a plurality of vertically extending channels. Methods include forming a gate dielectric material around the one or more shallow trench isolations extending in a word line direction. Methods include depositing a low work function material in the one or more shallow trench isolations extending in a word line direction. Methods include etching the low word function material to a height below a deposited height. Methods also include depositing a high work function material in the one or more shallow trench isolations extending in a word line direction, and etching the high work function material to a height below a deposited height. Methods include where a dielectric material is filled in the shallow trench isolation prior to etching the low work function material.

In embodiments, filling the dielectric material in the shallow trench isolation occurs prior to depositing the gate dielectric material and the low work function material. In further embodiments, methods include depositing a sacrificial material around the one or more shallow trench isolations, filling the dielectric material in the shallow trench isolation, and etching the sacrificial material to a height below a deposited height. Moreover, in embodiments, methods include filling the dielectric material in the shallow trench isolation after depositing the low work function material. Additionally or alternatively, methods include forming one or more source/drain regions, where the one or more source/drain regions are formed by ion implant, silicidation, or a combination thereof.

Such technology may provide numerous benefits over conventional systems and techniques. For example, the processes and systems may reduce off leakage current without impacting the overall function of the word line. Additionally, the processes and systems may significantly improve gate-induced drain leakage. These and other embodiments, along with many of their advantages and features, are described in more detail in conjunction with the below description and attached figures.

### BRIEF DESCRIPTION OF THE DRAWINGS

A further understanding of the nature and advantages of the disclosed technology may be realized by reference to the remaining portions of the specification and the drawings.

FIG. 1A shows a top plan view of an exemplary processing chamber according to embodiments of the present technology.

FIG. 1B illustrates a top view of a conventional 4F² memory array.

FIG. 1C illustrates a perspective view of a conventional 4F² memory array.

FIG. 2 shows selected operations in a formation method according to embodiments of the present technology.

FIG. 3A shows a perspective view of a semiconductor structure according to embodiments of the present technology with a dielectric material fill after shallow trench isolation formation.

FIG. 3B shows a perspective view of a semiconductor structure according to embodiments of the present technology patterned for second shallow trench isolation formation.

FIG. 3C shows a perspective view of a semiconductor structure according to embodiments of the present technology with a gate oxide and low work function material deposited word line isolations.

FIG. 3D shows a perspective view of a semiconductor structure according to embodiments of the present technology with the word line isolations filled.

FIG. 3E shows a perspective view of a semiconductor structure according to embodiments of the present technology with the low work function material etched back.

FIG. 3F shows a perspective view of a semiconductor structure according to embodiments of the present technology with a high work function material deposited in the word line isolations.

FIG. 3G shows a perspective view of a semiconductor structure according to embodiments of the present technology with the high work function material etched back.

FIG. 3H shows a perspective view of a semiconductor structure according to embodiments of the present technology with a low work function material deposited in the word line isolations over the high work function material.

FIG. 3I shows a perspective view of a semiconductor structure according to embodiments of the present technology with the low work function material etched back.

FIG. 3J shows a perspective view of a semiconductor structure according to embodiments of the present technology with doped source/drain regions.

FIG. 4A shows a perspective view of a semiconductor structure according to embodiments of the present technology with a spacer formed prior to the low work function material being deposited.

FIG. 4B shows a perspective view of a semiconductor structure according to embodiments of the present technology with the spacer etched formed prior to the low work function material being deposited.

FIG. 5A shows a perspective view of a semiconductor structure according to embodiments of the present technology where source/drain formation is conducted after depositing the low work function material over the high work function material.

FIG. 5B shows a perspective view of a semiconductor structure according to embodiments of the present technology where second source/drain regions are formed.

Several of the figures are included as schematics. It is to be understood that the figures are for illustrative purposes and are not to be considered of scale unless specifically stated to be of scale. Additionally, as schematics, the figures are provided to aid comprehension and may not include all aspects or information compared to realistic representations and may include exaggerated material for illustrative purposes.

In the appended figures, similar components and/or features may have the same reference label. Further, various components of the same type may be distinguished by following the reference label by a letter that distinguishes among the similar components. If only the first reference label is used in the specification, the description is applicable to any one of the similar components having the same first reference label irrespective of the letter.

### DETAILED DESCRIPTION

Historically, DRAM chip bit densities had been increasing by approximately 25% node over node. However, the node over node increase in bit density has trended down to closer to 20% for the more recent generations, mainly due to the challenges with scaling the cell area. Cell design architecture for modern DRAM technology has been based on 6F² geometry, where “F” is the minimum feature size for a given technology node. Switching from 6F² to 4F² cell architecture could result in a 33% increase in bit density at the same technology node. In addition, patterning difficulties for 4F₂ DRAM are greatly reduced as compared to 6F². This is due at least in part to the fact that in the 4F₂ DRAM scheme, the capacitor and bit line are located at two ends of a vertical cell transistor, instead of tightly packed on the same side as in 6F² DRAM.

However, the 4F² DRAM design comes with its own challenges. For example, 4F² memory cells have the transistor channel disposed between the bitline and the capacitor layers, leaving no common substrate connecting the channels, resulting in a floating body effect for these transistors. For instance, it is believed that conventional 4F² DRAM devices exhibit off-leakage current issues. Off-leakage current results from the floating body effect, such as hole accumulation in the body of a 4F² DRAM device due to the isolated channels. Electron-hole pairs can form in a semiconductor channels due to band-to-band tunneling. While the electrons can flow into the n-type source or drain regions of the transistor, the holes cannot. For 4F² DRAM devices without a substrate connection, the holes have no path to leave the channel and will continue to accumulate. Thus, the floating body effect may lead to channel activation without gate activation, which eventually translates into leakage current from the capacitor, or data storage side of the device. Attempts have been made to provide body connections utilizing a buried body contact scheme. However, such attempts can result in gate overlap to a source/drain junction edge, allowing undesired gate-induced drain leakage, or limited scalability to small dimensions. Moreover, such design schemes are also capable of producing high aspect ratio structures that challenge existing doping techniques.

Due at least in part to the floating body effect, vertical channel array transistors (VCATs) are more susceptible to elevated leakage current values, such as gate induced drain leakage. Moreover, gate induced drain leakage may further increase hole generation. Efforts have been made to decrease the work function of the word line material to decrease hole accumulation, but limits exist on how low the work function may go, as the threshold voltages of the VCAT is determined by the word line. Furthermore, at low work functions, resistivity and off leakage current increase, preventing hole mobility outside of source/drain regions.

The present technology overcomes these and other problems by providing a multi-zoned word line containing a low work function material and a high work function material. The low work function material may be formed adjacent to and overlapping source/drain regions of the word line while the high work function material may be formed adjacent to the channel regions. In such a manner, a high threshold voltage is maintained in channel regions, providing for excellent lower off current leakage. Moreover, the low work function material may reduce the electric field near source/drain regions, providing for lower gate induced drain leakage. Thus, unlike prior attempts, the present technology may provide a word line that maintains a necessary threshold voltage for low off current leakage while reducing the gate induced drain leakage, and even the floating body effect of a vertical channel array transistor (VCAT). Furthermore, the present technology may provide methods for forming VCATs with multi-material word lines.

Although the remaining disclosure will routinely identify specific deposition and etch processes utilized for forming vertical cell array transistors (VCATs), such as a 4F² DRAM device, it will be readily understood that the systems and methods are equally applicable to other DRAM devices, including gate-all-around and Schottky barrier VCATs, other devices suffering from a floating body effect, and orientations thereof, as well as processes for forming such devices. Accordingly, the technology should not be considered to be so limited as for use with these specific devices or systems alone. The disclosure will discuss one possible semiconductor device that may include one or more components, utilizing one or more word lines according to embodiments of the present technology before additional variations and adjustments to this apparatus according to embodiments of the present technology are described.

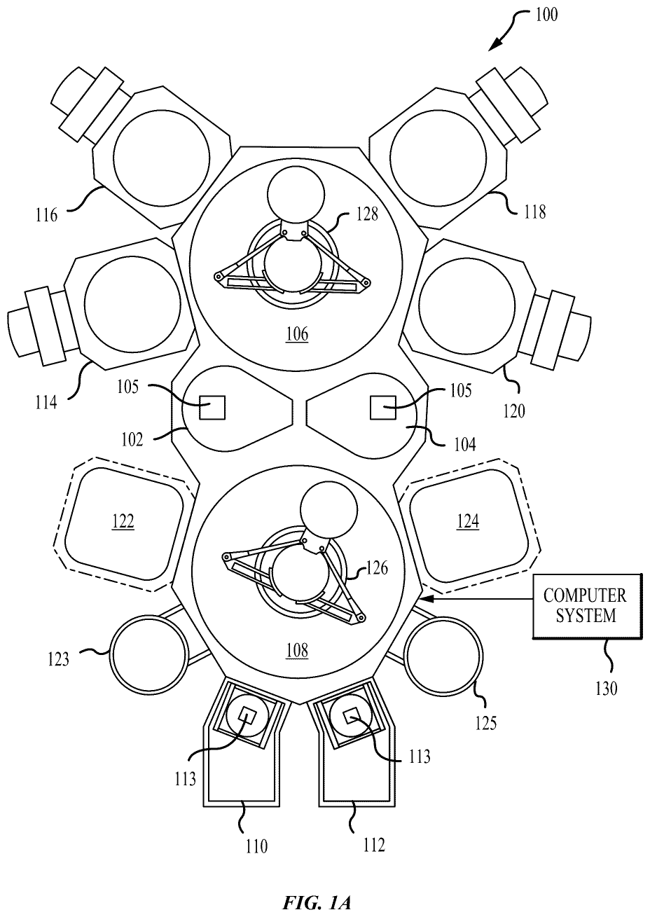

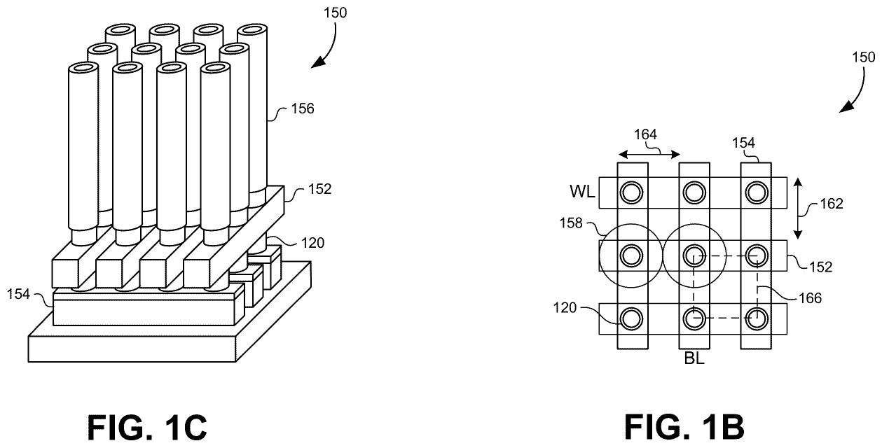

FIG. 1A illustrates a top plan view of a multi-chamber processing system 100, which may be specifically configured to implement aspects or operations according to some embodiments of the present technology. The multi-chamber processing system 100 may be configured to perform one or more fabrication processes on individual substrates, such as any number of semiconductor substrates, for forming semiconductor devices. The multi-chamber processing system 100 may include some or all of a transfer chamber 106, a buffer chamber 108, single wafer load locks 110 and 112, although dual load locks may also be included, processing chambers 114, 116, 118, 120, 122, and 124, preheating chambers 123 and 125, and robots 126 and 128. The single wafer load locks 110 and 112 may include heating elements 113 and may be attached to the buffer chamber 108. The processing chambers 114, 116, 118, and 120 may be attached to the transfer chamber 106. The processing chambers 122 and 124 may be attached to the buffer chamber 108. Two substrate transfer platforms 102 and 104 may be disposed between transfer chamber 106 and buffer chamber 108, and may facilitate transfer between robots 126 and 128. The platforms 102, 104 can be open to the transfer chamber and buffer chamber, or the platforms may be selectively isolated or sealed from the chamber to allow different operational pressures to be maintained between the transfer chamber 106 and the buffer chamber 108. Transfer platforms 102 and 104 may each include one or more tools 105, such as for orientation or measurement operations.

The operation of the multi-chamber processing system 100 may be controlled by a computer system 130. The computer system 130 may include any device or combination of devices configured to implement the operations described below. Accordingly, the computer system 130 may be a controller or array of controllers and/or a general purpose computer configured with software stored on a non-transitory, computer-readable medium that, when executed, may perform the operations described in relation to methods according to embodiments of the present technology. Each of the processing chambers 114, 116, 118, 120, 122, and 124 may be configured to perform one or more process steps in the fabrication of a semiconductor structure. More specifically, the processing chambers 114, 116, 118, 120, 122, and 124 may be outfitted to perform a number of substrate processing operations including dry etch processes, cyclical layer deposition, atomic layer deposition, chemical vapor deposition, physical vapor deposition, etch, pre-clean, degas, orientation, among any number of other substrate processes.

FIGS. 1B and 1C illustrate top and perspective views of a conventional 4F² memory array 150. The memory array 150 may include a plurality of word lines 152 that are arranged in a first layer over a substrate. The word lines 152 may be conductive traces that are used to select a word line of memory cells in the memory array 150. The memory array 150 may also include a plurality of bit lines 154 arranged in a second layer over a substrate. The plurality of bit lines may be conductive traces that are used to select a bit line of memory cells in the memory array 150. Activating one of the plurality of bit lines 154 and one of the plurality of word lines 152 may select an individual cell in the memory array 150. The first layer and the second layer may include different metal layers formed at different times during manufacturing process. For example, the first layer with the word lines 152 may be formed above the second layer with the bit lines 154 such that the two layers do not intersect.

A plurality of vertical memory cells may be arranged over intersections between the plurality of word lines 152 and the plurality of bit lines 154. Each of the plurality of vertical memory cells may include a vertical transistor, which may be referred to as a vertical pillar transistor or vertical column transistor. A channel material for the transistor may be formed from a single-crystal silicon pillar, or any other substrates discussed in greater detail below. This silicon channel may be formed by etching the substrate. Each of the plurality of vertical memory cells may also include a vertical capacitor 156. The vertical memory cell may operate by storing a charge on the vertical capacitors 156 to indicate a saved memory state. However, while FIGS. 1B and IC illustrate the arrangement of the vertical transistors and capacitors in a rectangular generally orthogonal grid pattern (where “generally orthogonal” may be within about 10° from orthogonal, such as less than or about 7.5°, such as less than or about 5°, such as less than or about 2.5°, such as less than or about 1° from orthogonal, or any ranges or values therebetween, where “generally” may be utilized to similarly vary “vertical”, “horizontal” and the like), it should be understood that other orientations are contemplated for use with the present technology. For instance, in embodiments, the capacitors and vertical transistors may be spaced in alternating rows that are offset by one half the distance between the vertical transistors. Namely, a first row of memory cells may be regularly spaced apart in a line in a first direction, and a second row of memory cells may also be regularly spaced apart in a line also in the first direction, but the second row of memory cells may be offset from the first row of memory cells, such as aligned approximately halfway between the vertical transistors and capacitors of the first row, in embodiments. Such a pattern may be referred to as a “honeycomb” or “hexagonal pattern” as compared to the square pattern illustrated in FIGS. 1B and 1C. Thus, it should be understood that any suitable orientation may be utilized with the present technology.

It is useful to characterize the dimensions of the unit cell area 166 for this conventional 4F² memory array for comparison to the simple memory array described below. For example, a capacitor footprint 158 may be defined as a circular area around each vertical capacitor 156. The capacitor footprint 158 may include the horizontal cross-sectional area of the capacitor expanded out until the cross-sectional area contacts a capacitor area from a neighboring memory cell. Assuming that the word line pitch 162 for the plurality of word lines 152 and the bit line pitch 164 for the plurality of bit lines 154 may be defined as 2F. This leads to an overall cross-sectional area of 4F² for a unit cell area 166.

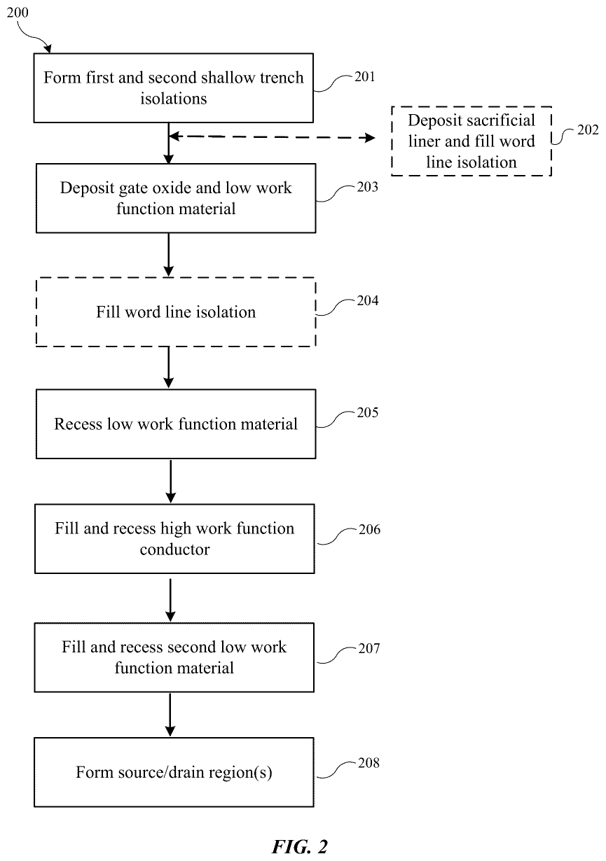

FIG. 2 shows exemplary operations in a method 200 according to some embodiments of the present technology. The method may be performed in a variety of processing chambers, including processing chamber 100 described above. Method 200 may include a number of optional operations, which may or may not be specifically associated with some embodiments of methods according to the present technology. For example, many of the operations are described in order to provide a broader scope of the structural formation, but are not critical to the technology, or may be performed by alternative methodology as would be readily appreciated. In addition, while the method may describe the formation method vertically, it should be understood that the other orientation from bit line to word line side may be utilized.

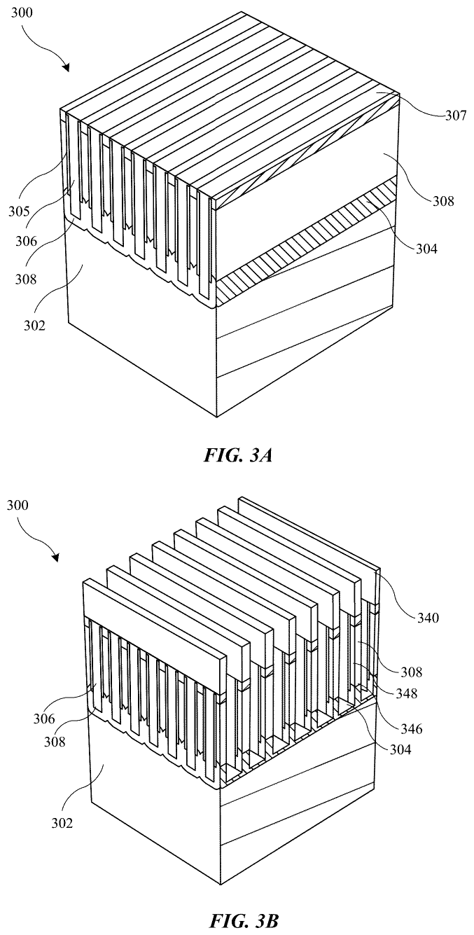

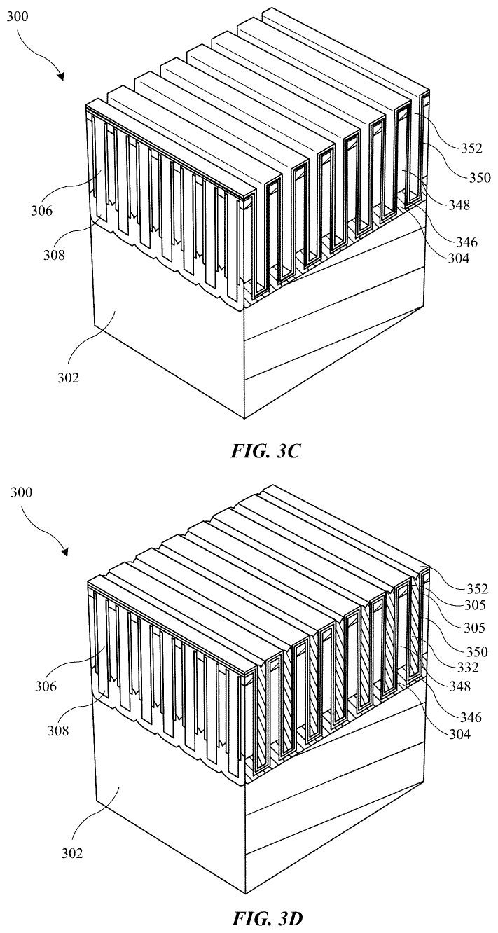

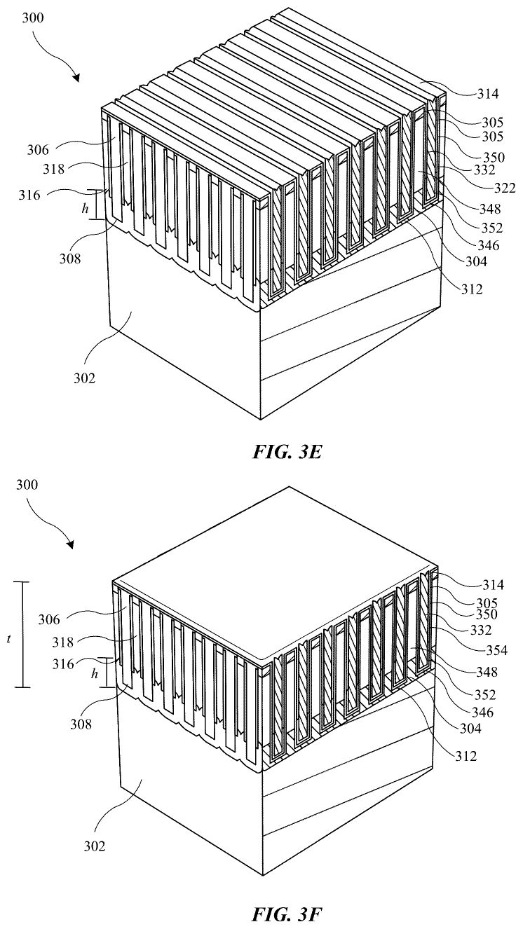

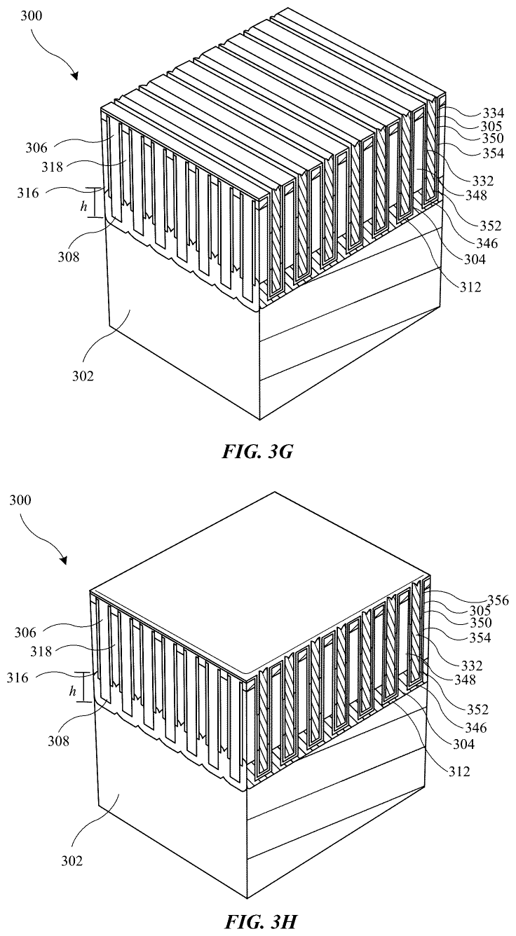

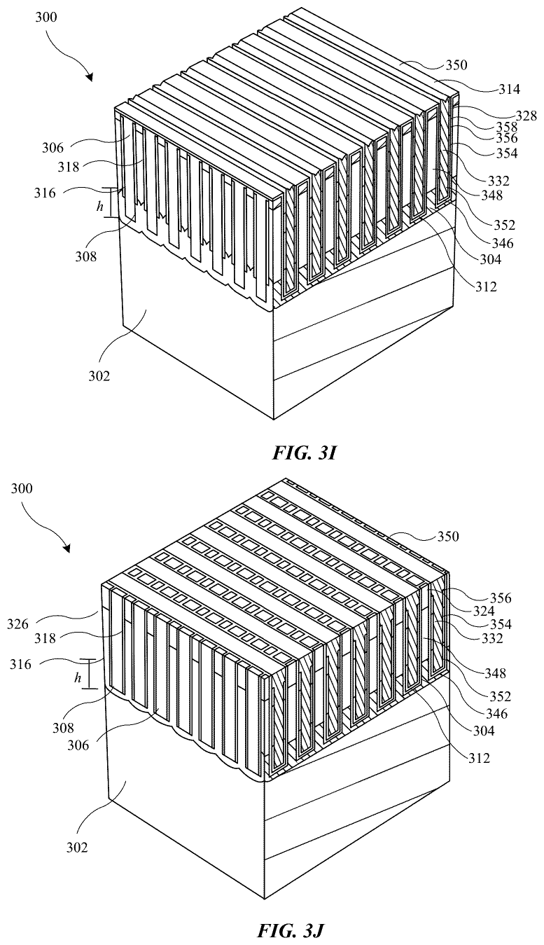

Method 200 may include additional operations prior to initiation of the listed operations. For example, additional processing operations may include forming structures on a semiconductor substrate, which may include both forming and removing material. Prior processing operations may be performed in the chamber in which method 200 may be performed, or processing may be performed in one or more other processing chambers prior to delivering the substrate into the semiconductor processing chamber in which method 200 may be performed. Regardless, method 200 may optionally include delivering a semiconductor substrate to a processing region of a semiconductor processing chamber, such as processing chamber 100 described above, or other chambers that may include components as described above. The substrate may be deposited on a substrate support/transfer platform, which may be a pedestal such as substrate support 104, and which may reside in a processing region of the chamber, such as processing region of processing chamber 120 described above. Method 200 describes operations shown schematically in FIGS. 3A-3J, the illustrations of which will be described in conjunction with the operations of method 200. It is to be understood that FIG. 3A-3J illustrate only partial schematic views, and a semiconductor substrate may include further components as illustrated in the figures, as well as alternative components, of any size or configuration that may still benefit from aspects of the present technology.

Method 200 may or may not involve optional operations to develop the semiconductor structure to a particular fabrication operation. It is to be understood that method 200 may be performed on any number of semiconductor structures 300 or substrates 302, as illustrated in FIG. 3A-3J, including exemplary structures on which a selective deposition material may be formed. As illustrated in FIG. 3A substrate 302 may be any number of materials, such as a base wafer or substrate made of silicon or silicon-containing materials, germanium, other substrate materials, as well as one or more materials that may be formed overlying the substrate during semiconductor processing.

In embodiments, the structure 300 may be a semiconductor substrate, including bulk substrates, epitaxially grown substrates, and/or silicon on insulator wafer. As used herein, the term “semiconductor substrate” refers to a substrate in which the entirety of the substrate is comprised of a semiconductor material. The semiconductor substrate may include any suitable semiconducting material and/or combinations of semiconducting materials for forming a semiconductor structure. For example, the semiconducting layer may comprise one or more materials such as crystalline silicon (e.g., Si<100> or Si<111>), silicon oxide, strained silicon, silicon germanium, doped or undoped polysilicon, doped or undoped silicon wafers, patterned or non-patterned wafers, doped silicon, germanium, gallium arsenide, or other suitable semiconducting materials. In embodiments, the semiconductor material is silicon (Si). In one or more embodiments, the semiconductor substrate 300 includes a semiconductor material, e.g., silicon (Si), carbon (C), germanium (Ge), silicon germanium (SiGe), germanium tin (GeSn), other semiconductor materials, or any combination thereof. In one or more embodiments, the substrate 302 includes one or more of silicon (Si), germanium (Ge), gallium (Ga), arsenic (As), or phosphorus (P). Although a few examples of materials from which the substrate may be formed are described herein, any material that may serve as a foundation upon which passive and active electronic devices (e.g., transistors, memories, capacitors, inductors, resistors, switches, integrated circuits, amplifiers, optoelectronic devices, or any other electronic devices) may be built falls within the spirit and scope of the present disclosure.

In embodiments, the semiconductor material may be a doped material, such as n-doped silicon (n-Si), or p-doped silicon (p-Si). In embodiments, the substrate may be doped using any suitable process such as an ion implantation process. As used herein, the term “n-type” refers to semiconductors that are created by doping an intrinsic semiconductor with an electron donor element during manufacture. The term n-type comes from the negative charge of the electron. In n-type semiconductors, electrons are the majority carriers and holes are the minority carriers. As used herein, the term “p-type” refers to the positive charge of a well (or hole). As opposed to n-type semiconductors, p-type semiconductors have a larger hole concentration than electron concentration. In p-type semiconductors, holes are the majority carriers and electrons are the minority carriers.

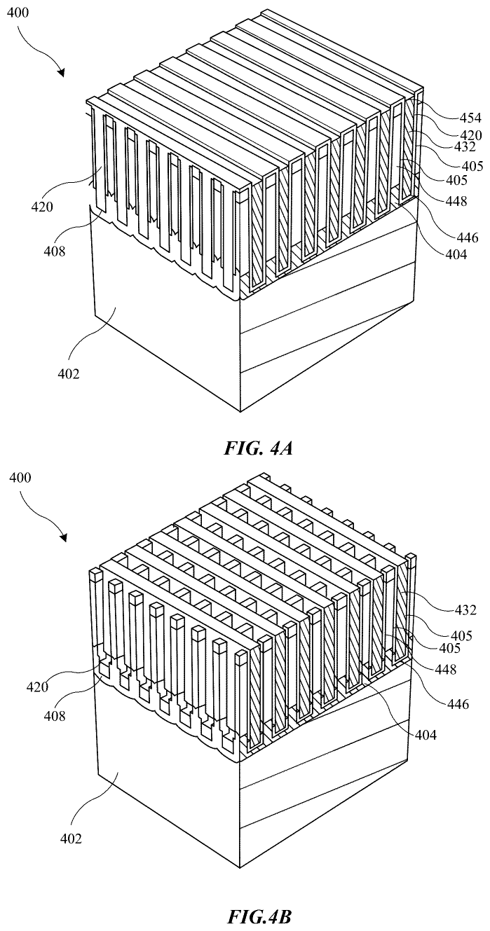

As illustrated in FIG. 3A, structure 300 is provided that includes a substrate 302 that has already undergone source/drain 304 formation, shallow trench isolation formation 308, and first dielectric material 306 fill in shallow trench isolations 308. However, as will be discussed in greater detail in regards to FIG. 4, it should be clear that first source/drain regions 304 may instead be formed after front side processing is complete. In addition, two or more walls 305 are formed between respective first shallow trench isolations 308, where the illustrated walls 305 are spaced apart in a horizontally extending row generally perpendicular to a word line direction in this embodiment. However, as would be understood by one having skill in the art, in embodiments, shallow trench isolations may be first cut in a direction generally parallel to the word line direction. In embodiments, when source/drain 304 formation is conducted as part of the front side processing, the formation may include one or more ion implants followed by a subsequent anneal process. The implant process may be a single implant or may include a series of multiple implants. When multiple implants are utilized, each implant may utilize the same ion, or different ions. Although, it should be understood that the source/drain region 304 may be formed from any suitable process. The method may include providing a semiconductor structure having first source/drain regions 304 for a plurality of vertical channels, and forming a plurality of word lines that contact the first source/drain regions. Overall, this process may incrementally form each stage of the transistor on top of a previous completed stage.

Moreover, while various deposition and fill processes will be described, it should be understood that, in embodiments, the semiconductor structure may be transferred to and between one or more process chambers 114, 116, 118, 120, 122, and 124 configured for deposition and/or fill processes, including chambers for: chemical vapor deposition (CVD), physical vapor deposition (PVD), atomic layer deposition (ALD), thermally enhanced chemical vapor deposition (CVD), plasma-enhanced chemical vapor deposition (PECVD), plasma enhanced atomic layer deposition (PEALD), or the like. Thus, unless specified, it should be understood that any one or more of the above methods may be utilized as known in the art. Similarly, the semiconductor structure may be transferred to and between one or more process chambers 114, 116, 118, 120, 122, and 124 configured for etching, such as one or more of inductively coupled plasma (ICP) etching, reactive ion etching (RIE), capacitively coupled plasma (CCP) etching, or the like, as well as other etching processes as known in the art.

Nonetheless, at operation 201, method 200 may include forming both first shallow trench isolations as illustrated in FIG. 3A and second shallow trench isolations 346. For instance, in embodiments, a substrate 302 may be loaded into load lock 110,112, and transferred to a process chamber (such as process chamber 114) via robots 126, 128, where the semiconductor structure 300 may undergo mask 340 formation and second shallow trench isolation 346 formation, which may also be referred to as word line trench formation herein as the second shallow trench isolations 346 may extend in a generally horizontal direction that is generally parallel to the word line direction, at operation 201. For instance, FIG. 3B illustrates forming mask 340, which may be any patterning mask as known in the art, and etching of walls 305 into channels 348 by etching in a direction extending in a second horizontal direction that is generally perpendicular to the first horizontal direction in embodiments, utilizing mask 340. Namely, as discussed above for the formation of shallow trench isolations 308 between walls 305, a pattern or mask 340 defining second shallow trench isolations 346 may be used to form the isolations between channels 348, which run in a row parallel or in plane with word lines, in this embodiment, formed by an etch process. The resulting channels 348 may have a uniform or nonuniform width, and/or a width generally equal to walls 305. The second shallow trench isolations 346 may serve to isolate neighboring channels 348. Thus, as illustrated in FIGS. 3A and 3B, a semiconductor structure 300 may be provided that includes first and second shallow trench isolations, where the first shallow trench isolation may contain a deposited or filled dielectric material as discussed above. It should be understood that the substrate may be transferred between each operation step, or only a portion of the operation steps, as some operation steps may be completed in the same processing chamber.

As illustrated in FIG. 3C, after operation 201, a gate dielectric material 350 may be formed over 350 along adjacent sidewalls 305 of respective word line trenches 346 in rows extending in the second horizontal direction (e.g. such that gate dielectric material 350 is generally parallel with the word line direction) at operation 203. The gate dielectric material 350 may be formed from oxides, including SiO or other similar materials, as known in the art. For example, in embodiments where the channel material is silicon, the gate dielectric material may be SiO which may be oxidized from the walls 305 to be used as the gate dielectric material 350.

However, in embodiments, dielectric material (e.g. gate oxide) 350 may be any material and deposited as known in the art. Notwithstanding the method, the gate dielectric material 350 extends generally along an external perimeter of the respective shallow trench isolation 346. The thickness of the gate dielectric material may be between about 1 nm and about 10 nm, such as from about 2 nm to about 9 nm, such as from about 3 nm to about 8 nm, such as from about 3 nm to about 6 nm, or any ranges or values therebetween.

Operation 203 may also include depositing a first word line material of the multi-layered word line. Thus, in embodiments a low work function material 352 may be deposited over gate dielectric material 350. The low work function material 352 is shown in FIG. 3C as being deposited generally along an exterior perimeter of the respective shallow trench isolation 346 overlying gate dielectric 350. The low work function material 352 may be deposited at a thickness of between about 1 nm and about 10 nm, such as from about 2 nm to about 9 nm, such as from about 3 nm to about 8 nm, such as from about 3 nm to about 6 nm, or any ranges or values therebetween. In such a manner, an adequate word line for low resistance may be formed without negatively effecting the pitch of the device.

In embodiments, the low work function material 352 may have a work function of less than 4.5 eV, such as less than or about 4.2 eV, such as less than or about 4 eV, such as less than or about 3.5 eV, such as less than or about 3 eV, such as less than or about 2.5 eV, such as less than or about 2 eV, such as less than or about 1.5 eV, or any ranges or values therebetween. For instance, in embodiments, the low work function material 352 may be a metal having a work function of less than 4.5 eV, such as less than or about 4.2 eV, an oxide thereof, a polysilicon, or other materials as known in the art. For instance, in embodiments, the low work function material 352 may be or include a metal or oxide containing aluminum (Al), niobium (Nb), Tantalum (Ta), a metallic substance having Fermi level lower than that of hafnium (Hf), a polysilicon, or combinations thereof.

However, in embodiments, the low work function material 352 may additionally or alternatively be selected to have a work function that is less than a work function of a high work function material 354, which will be discussed in greater detail below. Thus, in embodiments, the low work function material 352 may be a metal, an oxide thereof, a polysilicon, or the like, that has a work function that is at least 1% less than a work function of the high work function material 354, such as about 1.5% or less, such as about 2% or less, such as about 2.5% or less, such about 3% or less, such as about 3.5% or less, such as about 4% or less, such as about 4.5% or less, such as about 5% or less, or any ranges or values therebetween. Stated differently, in embodiments, the low work function material 352 may have a work function that is at least about 50 mV less than a work function of the high work function material 354, such as about 75 mV or less, such as about 100 mV or less, such as about 125 mV or less, such as about 150 mV or less, such as about 175 mV or less, such as about 200 mV or less, such as about 225 mV or less, such as about 250 mV or less, such as about 275 mV or less, such as about 300 mV or less than a work function of the high work function material 354, or any ranges or values therebetween.

In embodiments, it may be desirable to provide additional stability to the semiconductor structure. For instance, high aspect ratio structures, gate-all-around structures, as well as other structures as known in the art. Thus, in some embodiments, an optional operation 202 may be conducted and which may be shown more clearly in FIG. 4A and 4B. In such an embodiment, a sacrificial material layer 420 may be deposited in word line isolations 446 prior to forming the gate dielectric material 450 and low work function material 452. While various materials are contemplated, the sacrificial material 420 should exhibit an etch selectivity to the low work function material. Thus, in embodiments, the sacrificial material layer 420 may be or include, SiO₂, SiON, or other material as known in the art, and depending upon the material selected for the low work function material. The word line isolation 446 lined with sacrificial material layer 420 may then undergo a filling operation, forming second dielectric material 432 in sacrificial material layer 420 lined word line isolation 446. Furthermore, as illustrated in FIG. 4B, the sacrificial material layer 420 may be recessed after the filling operation. In such a manner, the second dielectric material 432 may provide additional stability to the structure during processing.

After recessing the sacrificial material layer 420, a gate dielectric material 350 may be deposited along the perimeter of isolation 346, such as along sidewalls 405 of the respective shallow trench isolation 346, and the remainder of the void space between dielectric 350 and second dielectric material 432, left by recessing of the sacrificial material 320 may be filled with the low work function material 352, such as shown more clearly in FIG. 3D, and as will be discussed in greater detail below.

For instance, if optional operation 202 is not conducted, after the gate dielectric material and low work function material are deposited in operation 203, the remainder of the shallow trench isolation 346 may be filled at operation 204. FIG. 3D illustrates the fill being conducted with a second dielectric material 332, which may be the same dielectric material as first dielectric material 306, gate dielectric material 350, or a different dielectric material according to any one or more of the materials discussed above or as known in the art. In embodiments, the first dielectric material 306, gate dielectric material 350, and/or second dielectric material 332 may be any one or more dielectric material(s), such as a silicon oxide, silicon oxycarbide, silicon oxynitride, silicon oxycarbonitride, combinations thereof, or other dielectric material as known in the art, formed utilizing any fill methods discussed above and as known in the art. Although the following description will regularly discuss silicon oxide or silicon nitride as a dielectric material and/or a spacer material, it is to be understood that any number of dielectric materials may be used in embodiments of the present technology, and the present technology should not be limited to any particular dielectric material in which features may be formed. Nonetheless, as will be discussed in greater detail below, it should be understood that other materials may be utilized at operation 204.

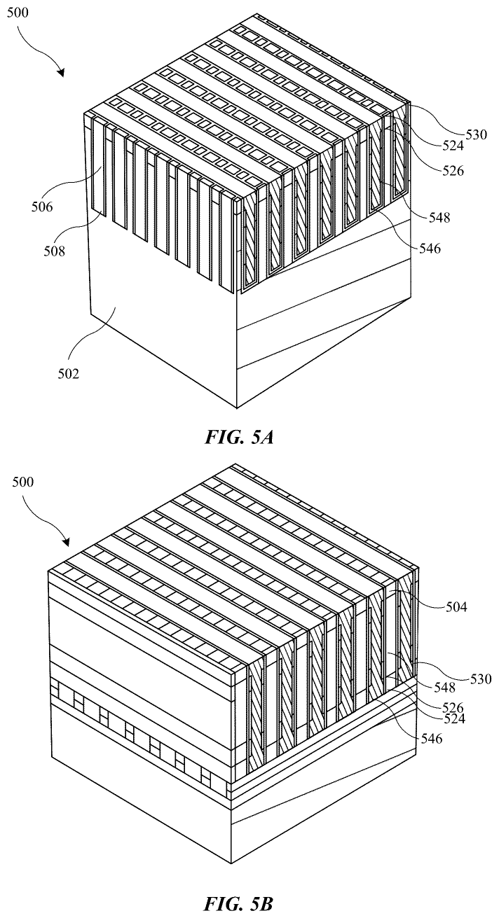

After fill operation 204 or 202, the low work function material 352 may be recessed at operation 205 as illustrated in FIG. 3E. In embodiments, the recessing operation may be any recessing operation as known in the art for recessing word line materials. In embodiments, the recessing operation may be selected to retain the gate dielectric 350, first dielectric material 306, and/or second dielectric material 350. Nonetheless, in embodiments, the low work function material 352 may be recessed to a depth between a midpoint of the shallow trench isolation and a trench height generally coplanar with one or more source/drain regions 304, or planned source drain regions, which will be discussed in greater detail in regards to FIGS. 5A and 5B, forming a first word line section. In embodiments, trench height t may be defined from a first end 312 adjacent to substrate 302 to a top surface 314 of the semiconductor structure 300.

Nonetheless, in embodiments, the low work function material 352 may be recessed to a depth between a midpoint of the shallow trench isolation and a trench height generally coplanar with a top surface 316 of one or more source/drain regions 304, or planned source drain regions. In such a manner, the low work function material 352 may form a first word line section that extends from a base or bottom of the word line and prevents overlap between the high work function material 354 and one or more source/drain regions 304. In addition, such a size and shape also allows a portion of the trench to be filled with a high work function material, allowing a higher threshold voltage in a central portion of the shallow trench isolation 346 and adjacent channels 348. In embodiments, the low work function material 352 may be recessed to a depth that is above a plane of a top surface 316 of one or more source/drain regions, in order to overlap a source/drain region adjacent to the top surface 316 and a channel region 318 of an adjacent channel 348. By extending to a height above a top surface 316 of an adjacent source/drain region 304, contact between the high work function material 354 and the source/drain regions 304 may be further reduced.

Thus, in embodiments, the low work function material 352 may be reduced to a height that is at least about 1% greater than a height h of an adjacent source/drain region (as illustrated in FIG. 3E, which may extend from substrate 302 to top surface 316), such as about 2% or greater, such as about 3% or greater, such as about 4% or greater, such as about 5% or greater, such as about 6% or greater, such as about 7% or greater, such as about 8% or greater, such as about 9% or greater, such as about 10% or greater, such as about 12.5% or greater, such as about 15% or greater, such as about 17.5% or greater, such as about 20% or greater, or any ranges or values therebetween.

In addition, in order to retain sufficient high work function material to provide good off current prevention, the low work function material 352 may be reduced to a height that is at least about 1% less than a midpoint of the respective shallow trench isolation 346, such as about 2% or less, such as about 3% or less, such as about 4% or less, such as about 5% or less, such as about 6% or less, such as about 7% or less, such as about 8% or less, such as about 9% or less, such as about 10% or less, such as about 12.5% or less, such as about 15% or less, such as about 17.5% or less, such as about 20% or less, such as about 22.5% or less, such as about 25% or less, such as about 27.5% or less, such as about 30% or less, such as about 32.5% or less, such as about 35% or less, such as about 37.5% or less, such as about 40% or less, such as about 42.5% or less, such as about 45% or less, such as about 47.5% or less, such as about 50% or less, or any ranges or values therebetween.

Notwithstanding the depth the low work function material 352 is recessed corresponding to the section height, operation 206 may include filling a high work function material 354 over a top surface of low work function material 352 in the recesses 322 formed between the gate dielectric 350 and the second dielectric material 332 by the removal of low work function material 352, as illustrated in FIG. 3F. Thus, in embodiments a high work function material 354 may be deposited over low work function material 352, and between gate dielectric material 350 and second dielectric material 332. The high work function material 354 may be deposited at a thickness (e.g., direction between dielectric material 332 and gate dielectric 350) of between about 1 nm and about 10 nm, such as from about 2 nm to about 9 nm, such as from about 3 nm to about 8 nm, such as from about 3 nm to about 6 nm, or any ranges or values therebetween. In such a manner, an adequate word line for low resistance may be formed without negatively effecting the pitch of the device.

In embodiments, the high work function material 354 may have a work function of greater than or about 2 eV, such as greater than or about 2.5 eV, such as greater than or about 3 eV, such as greater than or about 3.5 eV, such as greater than or about 4 eV, such as greater than or about 4.2 eV, such as greater than or about 4.5 eV, such as greater than or about 4.75 eV, such as greater than or about 5 eV, or any ranges or values therebetween. For instance, in embodiments, the high work function material 354 may be a metal having a work function of greater than or about 4.2 eV, such as greater than or about 4.5 eV, an oxide thereof, or other materials as known in the art. For instance, in embodiments, the high work function material 354 may be or include a metal or oxide containing molybdenum (Mo), Ruthenium (Ru), Platinum (Pt), Iridium (Ir), Tantalum (Ta), Rhodium (Rh), Palladium (Pd), a metallic substance having Fermi level lower than that of hafnium (Hf), other metals, nitrides, or oxides as known in the art, or combinations thereof. Moreover, in embodiments, if the low work function material is polysilicon, the high work function material may also include titanium nitride.

However, in embodiments, the high work function material 354 may additionally or alternatively be selected to have a work function that is greater than a work function of a low work function material, such as low work function material 352 and/or second low work function material 356 discussed in greater detail below. Thus, in embodiments, the high work function material 354 may be a metal, an oxide thereof, or the like, that has a work function that is at least 1% greater than a work function of the low work function material(s), such about 1.5% or greater, such as about 2% or greater, such as about 2.5% or greater, such as about 3% or greater, such as bout 3.5% or greater, such as about 4% or greater, such as about 4.5% or greater, such about 5% or greater, or any ranges or values therebetween. Stated differently, in embodiments, the high work function material 354 may have a work function that is at least about 50 mV greater than a work function of the low work function material(s), such as about 75 mV or greater, such as about 100 mV or greater, such as about 125 mV or greater, such as about 150 mV or greater, such as about 175 mV or greater, such as about 200 mV or greater, such as about 225 mV or greater, such as about 250 mV or greater, such as about 275 mV or greater, such as about 300 mV or greater than a work function of the high work function material 354, or any ranges or values therebetween.

Regardless of the material selected for the high work function material 354, the high work function material 354 may be recessed to a depth between a midpoint of the shallow trench isolation and a trench height generally coplanar with a bottom surface 326 of second source/drain regions 324 (shown in FIGS. 3J and 5A), or planned source drain regions, as illustrated in FIG. 3G. In such a manner, the high work function material 354 may form a second word line section having a high percentage of overlap with the channel region 318 of adjacent channels 348 without having significant overlap with source/drain (or planned source/drain regions) 304, 324. Thus, an improved threshold voltage may be achieved in channel regions 318 while also obtaining reductions in leakage current in source/drain regions. In embodiments, the high work function material 354 may be recessed to a depth that is below a plane of a bottom surface 326 of one or more second source/drain regions 324 in order to avoid overlap with second source/drain regions 324 of an adjacent channel 348. By recessing the height to a height below a bottom surface 326 of one or more second source/drain regions 324, contact between the high work function material 354 and the source/drain regions 324 may be further reduced.

Thus, in embodiments, the high work function material 354 may be reduced to a height that is at least about 1% less than a height of a bottom surface 326 of an adjacent second source/drain region 324, such as about 2% or less, such as about 3% or less, such as about 4% or less, such as about 5% or less, such as about 6% or less, such as about 7% or less, such as about 8% or less, such as about 9% or less, such as about 10% or less, such as about 12.5% or less, such as about 15% or less, such as about 17.5% or less, such as about 20% or less, such as about 25% or less, such as about 30% or less, or any ranges or values therebetween.

Notwithstanding the depth the high work function material 354 is recessed, operation 207 may include filling a second low work function material 356 over a top surface of high work function material 354 in the recesses 334 formed between the gate dielectric 350 and the second dielectric material 332 by the removal of high work function material 354, as illustrated in FIG. 3H. Thus, in embodiments a second low work function material 356 may be deposited over high work function material 354, and between gate dielectric material 350 and second dielectric material 332. The second low work function material 356 may be deposited at a thickness (e.g., direction between dielectric material 332 and gate dielectric 350) of between about 1 nm and about 10 nm, such as from about 2 nm to about 9 nm, such as from about 3 nm to about 8 nm, such as from about 3 nm to about 6 nm, or any ranges or values therebetween. In such a manner, an adequate word line for low resistance may be formed without negatively effecting the pitch of the device. Moreover, the second low work function material 356 may be any one or more of the low work function materials discussed in regards to low work function material 352 above, including the electrical properties discussed above. In embodiments, second low work function material 356 may be the same as low work function material 352, or may be different.

Moreover, at operation 207, the second low work function material 356 may be recessed from the upper surface 314 of the respective shallow trench isolation 346 in order to allow for isolation of the word line material with one or more dielectric materials (such as second dielectric material 332). Thus, in embodiments, the second low work function material 356 may be recessed such that an upper surface 358 of the second low work function material 356 is spaced apart from upper surface 314 of an adjacent channel 348 by a height of at least about 1% of a total trench height t of a respective shallow trench isolation, such as about 2% or greater, such as about 3% or greater, such as about 4% or greater, such as about 5% or greater, such as about 6% or greater, such as about 7% or greater, such as about 8% or greater, such as about 9% or greater, such as about 10% or greater, such as about 12.5% or greater, such as about 15% or greater, such as about 17.5% or greater, such as about 20% or less, or any ranges or values therebetween.

After as discussed above, after operation 207, a dielectric material, which may be the same or different than any one or more of the dielectric materials discussed above, may be filled in to the recess 328 formed by recessing of second low work function material 356. Thus, at operation 208, second source/drain regions 324 may be formed. Second source/drain regions 324 may be formed by any one or more of the methods discussed above for forming 304. In embodiments, second source/drain regions 324 may be the same, or may be formed in the same way as source/drain regions 304, or may be formed differently.

While not shown, in embodiments, it may be beneficial to remove the connection between adjacent word lines if a low work function word line material was introduced prior to dielectric material 332 fill. In such embodiments, the semiconductor structure may be flipped, or otherwise oriented to remove substrate 302, such as via polishing. Moreover, a portion of the source/drain 304, channels 348, and shallow trench isolations 346 may be removed, such as via polishing. In such a manner, a portion of the low work function material 352 may be removed, separating adjacent word lines from one another, reducing the likelihood of shorts.

However, in embodiments, it should be understood that one or both of first source/drain regions 304 and second source/drain regions 324 may instead be formed as Schottky contacts instead of the Ohmic contacts discussed above. Namely, in embodiments, such a contact as a source/drain region(s) may eliminate P-N junctions and reduce the floating body effect, and therefore further decreases in leakage current. For instance, referring to FIGS. 5A and 5B, at operation 207, a metal silicide contact 330 may be formed as second source/drain regions 524. In such an embodiment, the second source/drain region 324 may undergo a metallization process, such as silicidation to form a metallized interface. For instance, a metal layer may be applied over second source/drain regions 324 which is subsequently exposed to a silicidation process. In embodiments, the metal layer may be tungsten, molybdenum, titanium, zirconium, nickel, hafnium, cobalt, tin, tantalum, platinum, iron, niobium, palladium, a metal-containing species thereof, alloys thereof, or combinations thereof. Thus, the resulting interface may be a metallized layer of any one or more of the above metals and the channel material, such as silicon. In such an example only, the interface layer may be a titanium silicide, molybdenum silicide, hafnium silicide, or a combination thereof. The contact may also contain one or more ion implants, such as of phosphorus, arsenic, or some other material in order to produce a barrier height of greater than or about 0.60 V, and which may produce a barrier height of greater than or about 0.65 V, greater than or about 0.70 V, greater than or about 0.75 V, greater than or about 0.80 V, greater than or about 0.85 V, or more. Nonetheless, such silicidation procedures may be conducted at low temperatures.

In such embodiments, the source/drain regions 504 may be formed as part of “back side processing”. Thus, as illustrated in FIG. 5B, the semiconductor structure may be flipped such that the end adjacent to substrate 502 is now disposed above the formed channels and shallow trench isolations. Moreover, the substrate 502 may be removed, such as via polishing, exposing source/drain regions 504. Thus, source/drain regions 504 may be formed via an implant or silicidation process as discussed above. However, it should be understood that other methods of forming contacts or other source/drain regions may be utilized. In embodiments, such back side processing may also allow for the use of hybrid bonding to combine the capacitor on the channels discussed herein. Such a process may avoid the low temperature limitations commonly associated with Schottky type contacts.

Regardless of how or when the source/drain regions 304 and 324 are formed, the semiconductor structure 300/400/500 may re-enter a normal process flow for a vertical cell DRAM array, such as a 4F² DRAM array, and undergo one or more further processing steps. For instance, the semiconductor structure may undergo contact redistribution, bonding pad formation, and/or copper contact formation. Nonetheless, semiconductor structure may exhibit a drastically reduced gate induced leakage current, off current leakage, and/or floating body effect.

It should be appreciated that the specific steps illustrated in the figures provide particular methods of forming 4F² DRAM arrays according to various embodiments. Other sequences of steps may also be performed according to alternative embodiments. For example, alternative embodiments may perform the steps outlined above in a different order. Moreover, the individual steps illustrated in the figures may include multiple sub-steps that may be performed in various sequences as appropriate to the individual step. Furthermore, additional steps may be added or removed depending on the particular applications. Many variations, modifications, and alternatives also fall within the scope of this disclosure.

As used herein, the terms “about” or “approximately” or “substantially” may be interpreted as being within a range that would be expected by one having ordinary skill in the art in light of the specification.

In the foregoing description, for the purposes of explanation, numerous specific details were set forth in order to provide a thorough understanding of various embodiments. It will be apparent, however, that some embodiments may be practiced without some of these specific details. In other instances, well-known structures and devices are shown in block diagram form.

The foregoing description provides exemplary embodiments only, and is not intended to limit the scope, applicability, or configuration of the disclosure. Rather, the foregoing description of various embodiments will provide an enabling disclosure for implementing at least one embodiment. It should be understood that various changes may be made in the function and arrangement of elements without departing from the spirit and scope of some embodiments as set forth in the appended claims.

Specific details are given in the foregoing description to provide a thorough understanding of the embodiments. However, it will be understood that the embodiments may be practiced without these specific details. For example, circuits, systems, networks, processes, and other components may have been shown as components in block diagram form in order not to obscure the embodiments in unnecessary detail. In other instances, well-known circuits, processes, algorithms, structures, and techniques may have been shown without unnecessary detail in order to avoid obscuring the embodiments.

Also, it is noted that individual embodiments may have been described as a process which is depicted as a flowchart, a flow diagram, a data flow diagram, a structure diagram, or a block diagram. Although a flowchart may have described the operations as a sequential process, many of the operations can be performed in parallel or concurrently. In addition, the order of the operations may be re-arranged. A process is terminated when its operations are completed, but could have additional steps not included in a figure. A process may correspond to a method, a function, a procedure, a subroutine, a subprogram, etc. When a process corresponds to a function, its termination can correspond to a return of the function to the calling function or the main function.

The term “computer-readable medium” includes, but is not limited to portable or fixed storage devices, optical storage devices, wireless channels and various other mediums capable of storing, containing, or carrying instruction(s) and/or data. A code segment or machine-executable instructions may represent a procedure, a function, a subprogram, a program, a routine, a subroutine, a module, a software package, a class, or any combination of instructions, data structures, or program statements. A code segment may be coupled to another code segment or a hardware circuit by passing and/or receiving information, data, arguments, parameters, or memory contents. Information, arguments, parameters, data, etc., may be passed, forwarded, or transmitted via any suitable means including memory sharing, message passing, token passing, network transmission, etc.

Furthermore, embodiments may be implemented by hardware, software, firmware, middleware, microcode, hardware description languages, or any combination thereof. When implemented in software, firmware, middleware or microcode, the program code or code segments to perform the necessary tasks may be stored in a machine readable medium. A processor(s) may perform the necessary tasks.

In the foregoing specification, features are described with reference to specific embodiments thereof, but it should be recognized that not all embodiments are limited thereto. Various features and aspects of some embodiments may be used individually or jointly. Further, embodiments can be utilized in any number of environments and applications beyond those described herein without departing from the broader spirit and scope of the specification. The specification and drawings are, accordingly, to be regarded as illustrative rather than restrictive.

Additionally, for the purposes of illustration, methods were described in a particular order. It should be appreciated that in alternate embodiments, the methods may be performed in a different order than that described. It should also be appreciated that the methods described above may be performed by hardware components or may be embodied in sequences of machine-executable instructions, which may be used to cause a machine, such as a general-purpose or special-purpose processor or logic circuits programmed with the instructions to perform the methods. These machine-executable instructions may be stored on one or more machine readable mediums, such as CD-ROMs or other type of optical disks, floppy diskettes, ROMs, RAMS, EPROMs, EEPROMs, magnetic or optical cards, flash memory, or other types of machine-readable mediums suitable for storing electronic instructions. Alternatively, the methods may be performed by a combination of hardware and software.

what is claimed is:

1. A vertical cell array transistor (VCAT), comprising:
one or more bit lines arranged in a first horizontal direction;
one or more word lines arranged in a second horizontal direction;
one or more channels extending in a vertical direction that is generally orthogonal to the first horizontal direction and the second horizontal direction such that the one or more bit lines intersect with a source/drain region of the one or more channels, and the one or more word lines intersect with a gate region of the one or more channels;
wherein at least one word line of the one or more word lines comprises a first section adjacent to the source/drain region and a second section adjacent to the gate region, wherein the second section comprises a high work function material and the first section comprises a low work function material.

2. The vertical cell array transistor (VCAT) of claim 1, wherein the low work function material has a lower work function than the high work function material.

3. The vertical cell array transistor (VCAT) of claim 1, wherein the at least one word line comprises a third section adjacent to a second source/drain region.

4. The vertical cell array transistor (VCAT) of claim 3, wherein the third section comprises a second low work function material.

5. The vertical cell array transistor (VCAT) of claim 4, wherein the second low work function material is the same material as the low work function material or is a different material than the low work function material.

6. The vertical cell array transistor (VCAT) of claim 1, wherein the high work function material exhibits a work function that is at least about 2% greater than a work function of the low work function material.

7. The vertical cell array transistor (VCAT) of claim 1, wherein the low work function material comprises a work function of less than or about 4.2 eV.

8. The vertical cell array transistor (VCAT) of claim 7, wherein the high work function material comprises a work function of greater than 4.2 eV.

9. The vertical cell array transistor (VCAT) of claim 1, wherein the source/drain region comprises a Schottky contact or an Ohmic contact.

10. The vertical cell array transistor (VCAT) of claim 1, further comprising a gate extending in the second horizontal direction and formed around at least a portion of the one or more channels.

11. A vertical cell array transistor (VCAT), comprising:
a plurality of bit lines arranged in a first horizontal direction;
a plurality of word lines arranged in a second horizontal direction;
a plurality of channels extending in a vertical direction that is generally orthogonal to the first horizontal direction and the second horizontal direction such that the plurality of bit lines intersect with a source/drain region of the plurality of channels, and the plurality of word lines intersect with a gate region of the plurality of channels;
wherein at least one word line of the plurality of word lines comprises a first section adjacent to the source/drain region, a second section adjacent to the gate region, and a third section adjacent to a second source/drain region wherein the second section comprises a high work function material and the first section and third section comprises a low work function material.

12. The vertical cell array transistor (VCAT) according to claim 11, wherein the first section extends from a bottom of the at least one word line to a height above a plane generally coplanar with an upper surface of an adjacent source/drain region.

13. The vertical cell array transistor (VCAT) according to claim 12, wherein the second section extends from an upper surface of the first section to a height below a plane generally coplanar with a lower surface of the second source/drain region.

14. The vertical cell array transistor (VCAT) according to claim 13, wherein the third section extends from an upper surface of the second section to a height below an upper surface of an adjacent channel.

15. The vertical cell array transistor (VCAT) according to claim 11, wherein the second section comprises molybdenum, and the first section and the third section comprise polysilicon.

16. A method of forming a vertical cell array transistor (VCAT), comprising:
etching a substrate to form one or more shallow trench isolations and a plurality of vertically extending channels;
forming a gate dielectric material around the one or more shallow trench isolations extending in a word line direction;
depositing a low work function material in the one or more shallow trench isolations extending in a word line direction;
etching the low work function material to a height below a deposited height;
depositing a high work function material in the one or more shallow trench isolations extending in a word line direction; and
etching the high work function material to a height below a deposited height;
wherein a dielectric material is filled in the shallow trench isolation prior to etching the low work function material.

17. The method of claim 16, comprising filling the dielectric material in the one or more shallow trench isolations prior to depositing the gate dielectric material and the low work function material.

18. The method of claim 17, further comprising depositing a sacrificial material around the one or more shallow trench isolations, filling the dielectric material in the shallow trench isolation, and etching the sacrificial material to a height below a deposited height.

19. The method of claim 16, comprising filling the dielectric material in the shallow trench isolation after depositing the low work function material.

20. The method of claim 16. further comprising forming one or more source/drain regions, wherein the one or more source/drain regions are formed by ion implant, by silicidation, or a combination thereof.
